(19) United States
(12) Patent Application Publication
(10) Pub. No.: US 2024/0309194 A1
(43) Pub. Date: Sep. 19, 2024

(54) FLEXIBLE BIODEGRADABLE SUBSTRATE MATERIAL FOR PHOTOVOLTAIC CELLS

(71) Applicants: YILDIZ TEKNIK UNIVERSITESI, ISTANBUL (TR); YILDIZ TEKNIK UNIVERSITESI TEKNOLOJI TRANSFER OFISI, ISTANBUL (TR)

(72) Inventors: Serap GUNES, Istanbul (TR); Macide CANTURK RODOP, Istanbul (TR); Cihangir KAHVECI, Istanbul (TR)

(73) Assignees: YILDIZ TEKNIK UNIVERSITESI, ISTANBUL (TR); YILDIZ TEKNIK UNIVERSITESI TEKNOLOJI TRANSFER OFISI, ISTANBUL (TR)

(21) Appl. No.: 18/245,729

(22) PCT Filed: Mar. 11, 2022
(86) PCT No.: PCT/TR2022/050223

§ 371 Date: Mar. 17, 2023

(51) Int. Cl. C08L 29/04; C08L 71/02; H01L 23/14; H01L 31/042

(52) U.S. Cl. CPC C08L 29/04; C08L 71/02; H01L 23/145; H01L 31/042; C08L 2203/204; C08L 2205/035

(57) ABSTRACT

A flexible substrate material is provided. The substrate material can be used in photovoltaic cells or solar panels obtained from these, electricity generation charging stations or signal devices to be integrated into the human body, and the substrate material does not cause toxic effects for nature and human health. The substrate material is a composite material mainly consisting of natural materials.

### CROSS REFERENCE TO THE RELATED APPLICATIONS

This application is the national phase entry of International Application No. PCT/TR2022/050223, filed on Mar. 11, 2022, the entire contents of which are incorporated herein by reference.

### TECHNICAL FIELD

The present invention pertains to the technical field of renewable energy generation and relates to a flexible substrate material that can be used in photovoltaic cells or solar panels obtained from these, electricity generation charging stations or signal devices to be integrated into the human body, and that does not cause toxic effects for nature and human health.

### BACKGROUND

Due to the threat of extinction of fossil fuels, environmental concerns and global warming, the integration of electrical energy produced from renewable sources into the system has gained a serious importance in Turkey as well as in all over the world. As it is known, approximately 73% of the energy consumed in Turkey is of foreign origin, and our dependence on foreign energy is increasing day by day. The most important indicator of this dependence is the amount of natural gas used in electrical energy generation. While the proportion of natural gas in world electricity generation is approximately 20%, this ratio is around 50% in Turkey. For this reason, the trend of using renewable energy sources for electricity generation is increasing day by day in Turkey.

As a result of the political and technical success in electricity generation by photovoltaic cells solar panels are being spread over wider areas. Although the glass and aluminum materials in the solar panels do not pose a big problem for the environment, the panels made of solar cells contain various heavy metals, additives (semiconductors), and chemicals that may be harmful to human health and nature. Said photovoltaic cells or solar panels contain arsenite, lead, copper, gallium, cadmium telluride, cadmium sulfide, polyvinyl fluoride, selenium, silicon and derivative compounds as components harmful for humans and nature. For this reason, measures should be taken due to the presence of the said compounds, both during the construction of the panels and in the removal and disposal thereof in the future after they have been used for 20 years. Since the existing photovoltaic cells or solar panels have to be replaced after about 20 years, the production continues and the circulation of the said heavy metals continues.

The substrate materials used in the literature are generally produced from petroleum and derivative materials. Petroleum and derivative materials can cause toxic effects for nature and human health. For this reason, it is aimed to reduce the use of petroleum and derivative materials in the relevant technical field.

Solar panels are a costly product as a first investment; in order to reduce costs, it is also required to reduce the production costs of flexible substrate materials.

In the upcoming periods, human/device compatibility will become more important. It will be required that said human/device materials have features such as being able to integrate into people's bodies, be biocompatible for the parts they are integrated with, to charge their phones while walking on the road or to send signals to their brains. In this case, it will be important to obtain biocompatible base materials for photovoltaic or solar panels in the upcoming periods.

As a result, in the related technical field, it has become a necessity to obtain substrate materials which are flexible and do not contain the components to create toxic effects for photovoltaic and solar panel systems, which will become more important in the upcoming years.

### SUMMARY

The present invention relates to a substrate material for photovoltaic and solar panels, which eliminates the disadvantages in the related technical field and provides additional advantages to the related technical field.

The main purpose of the present invention is to present a substrate material for photovoltaic and solar panels that does not contain any toxic effects for nature and human health.

Another object of the present invention is to present a substrate material for photovoltaic and solar panels with high flexibility.

In another aspect, the present invention is to present a substrate material that is compatible with and adheres to the human body, has properties that do not contain any toxic effects for the human body, and can be used in electric charging stations or batteries that can be produced in the upcoming period.

### DETAILED DESCRIPTION OF THE EMBODIMENTS

In this detailed description, the subject of the present invention pertains to the technical field of renewable energy generation and relates to a flexible substrate material that can be used in photovoltaic cells or solar panels obtained from these, electricity generation charging stations or signal devices to be integrated into the human body, and that does not cause toxic effects for nature and human health, and it is explained with examples that will not have any limiting effect only for a better understanding of the subject.

The inventive substrate material for photovoltaic and solar panels is a flexible, biodegradable material that does not cause toxic effects for nature and human health.

The substrate material of the present invention is a composite material mainly consisting of natural materials. The said composite material is a thin film. With the biodegradable components in its structure, it is possible to obtain substrate materials that are both flexible and does not contain any toxic effects, which can be used in photovoltaic and solar panels.

The substrate material of the present invention is biodegradable and dissolves in water and is disposed of, thus it will not be waste for nature.

The substrate material of the present invention contains components that will not cause any toxic effects and are not subjected to a chemical process during production.

The substrate material of the present invention may contain at least one of the polyvinyl alcohol or polyvinyl alcohol or cross-linked biopolymers, hydrogels as the essential component.

In a preferred embodiment of the present invention, the substrate material contains polyvinyl alcohol compound as an essential component. Polyvinyl alcohol provides the substrate material with water solubility, non-toxicity, mechanical strength and flexibility. Polyvinyl alcohol can be obtained by dissolving in water to obtain the thin film to be used as a substrate material. In this way, there is no need to use chemical solvents that may have toxic effects in the production of the substrate material of the present invention.

The substrate material of the present invention contains water-soluble polyvinyl alcohol component in the range of 1-3% by weight.

The substrate material of the present invention contains polyvinyl alcohol component as an essential component, as well as starch to provide mechanical strength and stabilizer properties. Rice, wheat, potato or corn starch types can be used as said starch. In the present invention, wheat starch is preferred as starch.

The substrate material of the present invention contains the starch component in the range of 6-20 mg.

The substrate material of the present invention contains at least one component obtained from plants. The substrate material of the present invention can have sufficient mechanical strength and flexibility since it contains at least one component obtained from plants.

It is the presence of at least one of the fern, onion juice and grass group as a component obtained from the said plants.

The substrate material of the present invention contains powders or juices of grass, onions and ferns as components.

The substrate material of the present invention contains at least one component obtained from plants in the range of 100-150 mg.

The substrate material of the present invention is a thin film with a flexible and highly elasticity structure. Said thin film can also be applied to any part of the skin and has a sticky consistency. The substrate material of the present invention contains xanthan gum component in order to ensure that it has the desired consistency and stability. In addition to all these features, xanthan gum is included as a component in the production of substrate material as it is a good lubricant and emulsion stabilizer. Preferably, the substrate material contains the xanthan gum component in the range of 10-30 mg.

The substrate material contains polyethylene glycol, which will contribute to its elasticity by providing elasticity. One of the PEG400, PEG600, PEG4000 and PEG6000 compounds is selected as the said polyethylene glycol component. Preferably the polyethylene glycol compound is PEG600.

The substrate material of the present invention contains a polyethylene glycol component in the range of 100-200 mg.

The substrate material contains thickening agent, thickener, egg white to provide strength.

The substrate material of the present invention contains an egg white component in the range of 30-100 microliters.

The substrate material contains at least one gelatin component. Preferably substrate material contains at least one gelatin derived from calf or cattle. Said gelatin component is present in the substrate material in the range of 3-10 mg.

The substrate material of the present invention contains aloe vera juice obtained from aloe vera leaves in the range of 10-100 microliters in order to further increase the elasticity.

The substrate material of the present invention includes
polyvinyl alcohol,
herbal component containing at least one of the grass, fern and onion juice groups,
at least one of xanthan gum or starch components or their mixtures
calf or bovine gelatin (in case it is sticky to the human body)
polyethylene glycol,
egg white
juice obtained from aloe vera leaves
the water component as the balance.

The substrate material of the present invention contains polyvinyl alcohol, fern, onion, grass, xanthan gum, gelatin, polyethylene glycol, starch, egg white, aloe vera juice components obtained from aloe vera leaves.

As the first step in obtaining the substrate material of the present invention, the dissolution of polyvinyl alcohol in water is carried out. The said process is carried out at room temperature. Polyvinyl alcohol is added to the water in the range of 1% to 3% by weight. The aqueous PVA solution is mixed at room temperature or at 45° C. in a magnetic stirrer. Grass, fern, xanthan gum and/or gelatin are added to an agate mortar. By adding water at the level of microliters, these materials are completely dissolved and gelled, then PEG600, egg white, onion juice are added in microliters and mixed. PVA-water solution is added by dripping onto the mixture until it becomes a fluid consistency. Then, the obtained mixture is poured on the glass and obtained as a thin film.

The substrate material of the present invention is characterized in that it includes
Polyvinyl alcohol in the range of 1% to 3% by weight,
6 to 20 mg of starch component,
A mixture of onion juice, fern powder, grass in the range of 100 to 150 mg,
Xanthan gum in the range of 10 to 30 mg,
PEG in the range of 100 to 200 mg,
Egg whites in the range of 30 to 100 microliters,
Aloe vera juice in the range of 10 to 100 mg,
Gelatin in the range of 3 to 10 mg, and
Water component.

The substrate material of the present invention contains components that are biocompatible and biodegradable in the environment. In this way, a substrate material can be obtained that can decompose in the nature and does not create any toxic effects for the human body and can be used in photovoltaic or solar panels.

The substrate material of the present invention is in the form of a thin film with highly flexible properties. The substrate material can become transparent by varying grass and fern concentrations and/or not adding. As the said substrate material has the high flexibility, it can be adhered to every part of the skin and can be kept stable.

The substrate material of the present invention is a material with a mechanical strength that can be used in photovoltaic or solar panels.

Water is used as a solvent to obtain the substrate material of the present invention, and room temperatures can be sufficient. Said substrate material is water soluble. In order to delay its water solubility, the substrate material may contain water-retarding agents. Silicone gel dissolved in toluene, polyacrylic spray can be used as the said water-retarding agent. Preferably, the water-retarding agent includes silicone gel and toluene components. Preferably, it can be obtained as a mixture of silicone gel and toluene and can be obtained by brushing or spraying polyacrylic spray on the surface of the substrate.

The scope of the protection of the present invention is set forth in the annexed claims and certainly cannot be limited to exemplary explanations in this detailed description. It is evident that skilled person in the art can provide similar embodiments in the light of the explanations above without departing from the main theme of the present invention.

What is claimed is:

1. A substrate material, comprising
polyvinyl alcohol,
at least one selected from the group consisting of a grass, onion juice and fern powders or juices, or mixtures or all of the components of the grass, the onion juice and the fern powders or juices,
at least one selected from the group consisting of a starch, xanthan gum or mixtures of the starch and the xanthan gum
a polyethylene glycol (PEG),
an egg white
aloe vera juice obtained from aloe vera leaves
a calf or bovine gelatin
water component as a balance
wherein the substrate material is configured in photovoltaic cells or solar panels obtained from these, electricity generation charging stations, or signal devices to be integrated into a human body, and the substrate material does not cause toxic effects for nature and human health.

2. The substrate material according to claim 1, wherein the substrate material comprises the starch in a range of 6-20 mg.

3. The substrate material according to claim 1, wherein the xanthan gum is in a range of 10-30 mg.

4. The substrate material according to claim 1, wherein the PEG is one selected from the group consisting of compounds PEG300, PEG400, PEG600, PEG4000 and PEG6000.

5. The substrate material according to claim 4, wherein the PEG is the PEG600.

6. The substrate material according to claim 4, wherein the PEG is in a range of 100-200 mg.

7. The substrate material according to claim 1, wherein the egg white is in a range of 30-100 microliters.

8. (canceled)

9. The substrate material according to claim 1, wherein the calf or bovine gelatin comprises a gelatin in a range of 3-10 mg.

10. The substrate material according to claim 1, wherein the polyvinyl alcohol is in a range of 1-3% by weight in water.

11. The substrate material according to claim 1, wherein the substrate material comprises the aloe vera juice in a range of 10 to 100 microliters.

12. The substrate material according to claim 1, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.

13. The substrate material according to claim 1, wherein the substrate material comprises
the polyvinyl alcohol in a range of 1% to 3% by weight,
6 to 20 mg of the starch,
the mixture of the onion juice, the fern powder, and the grass in a range of 100 to 150 mg,
the xanthan gum in a range of 10 to 30 mg,
the PEG in a range of 100 to 200 mg,
the egg whites in a range of 30 to 100 microliters,
the aloe vera juice in a range of 10 to 100 mg,
the calf or bovine gelatin in a range of 3 to 10 mg, and
the water component.

14. The substrate material according to claim 5, wherein the PEG is in a range of 100-200 mg.

15. The substrate material according to claim 2, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.

16. The substrate material according to claim 3, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.

17. The substrate material according to claim 4, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.

18. The substrate material according to claim 5, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.

19. The substrate material according to claim 6, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.

20. The substrate material according to claim 7, wherein the substrate material comprises
the polyvinyl alcohol,
the starch,
the xanthan gum
the PEG,
the egg white
the calf or bovine gelatin
the grass,
the fern powders,
the aloe vera juice
the onion juice
the water component.
